(19) United States
(12) Patent Application Publication
(10) Pub. No.: US 2024/0339394 A1
(43) Pub. Date: Oct. 10, 2024

(54) PARTIALLY SHIELDED SEMICONDUCTOR DEVICE AND METHOD FOR MAKING THE SAME

(71) Applicant: STATS ChipPAC Pte. Ltd., Singapore (SG)

(72) Inventors: JinHee JUNG, Incheon (KR); ChangOh KIM, Incheon (KR)

(21) Appl. No.: 18/605,842

(22) Filed: Mar. 15, 2024

(30) Foreign Application Priority Data
Apr. 4, 2023 (CN) 202310351921.1

(51) Int. Cl. H01L 23/498; H01L 21/56; H01L 23/00; H01L 23/552; H01L 25/065; H01L 25/16

(52) U.S. Cl. CPC H01L 23/49894; H01L 21/56; H01L 23/552; H01L 24/13; H01L 24/16; H01L 25/0655; H01L 25/16; H01L 2224/13016; H01L 2224/16227

(57) ABSTRACT

A partially shielded semiconductor device and a method for making the same are provided. The method may include: providing a package including: a substrate; an electronic component mounted on the substrate; an encapsulant formed on the substrate and encapsulating the electronic component; and a coating layer formed on the substrate and adjacent to the encapsulant; performing a laser hatching process on the encapsulant and a portion of the coating layer adjacent to the encapsulant to remove the portion of the coating layer to form a trench between the encapsulant and the coating layer; and electroless-plating a conductive material to cover the encapsulant and fill the trench between the encapsulant and the coating layer.

### TECHNICAL FIELD

The present application generally relates to semiconductor technology, and more particularly, to a partially shielded semiconductor device and a method for making the same.

### BACKGROUND OF THE INVENTION

The semiconductor industry is constantly faced with complex integration challenges as consumers want their electronics to be smaller, faster and higher performance with more and more functionalities packed into a single device. Antenna-in-Package (AiP) has emerged as the mainstream antenna packaging technology for various applications. However, the conventional AiP technology is complex, resulting in excess cost and low reliability. Therefore, a need exists for an AiP package with improved reliability.

### SUMMARY OF THE INVENTION

An objective of the present application is to provide a method for making a partially shielded semiconductor device with improved reliability.

According to an aspect of embodiments of the present application, a method for making a partially shielded semiconductor device. The method may include: providing a package including: a substrate; an electronic component mounted on the substrate; an encapsulant formed on the substrate and encapsulating the electronic component; and a coating layer formed on the substrate and adjacent to the encapsulant; performing a laser hatching process on the encapsulant and a portion of the coating layer adjacent to the encapsulant to remove the portion of the coating layer to form a trench between the encapsulant and the coating layer; and electroless-plating a conductive material to cover the encapsulant and fill the trench between the encapsulant and the coating layer.

According to another aspect of embodiments of the present application, a partially shielded semiconductor device is provided. The partially shielded semiconductor device may include: a substrate; an electronic component mounted on the substrate; an encapsulant formed on the substrate and encapsulating the electronic component; a coating layer formed between the substrate and the encapsulant; and an electromagnetic interference (EMI) shield covering the encapsulant.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 is a cross-sectional view illustrating a partially shielded semiconductor device.

FIGS. 2A to 2G are cross-sectional views illustrating various steps of a method for making a partially shielded semiconductor device according to an embodiment of the present application.

FIGS. 3A to 3G are cross-sectional views illustrating various steps of a method for making a partially shielded semiconductor device according to another embodiment of the present application.

FIG. 4 is a cross-sectional view illustrating a partially shielded semiconductor device according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

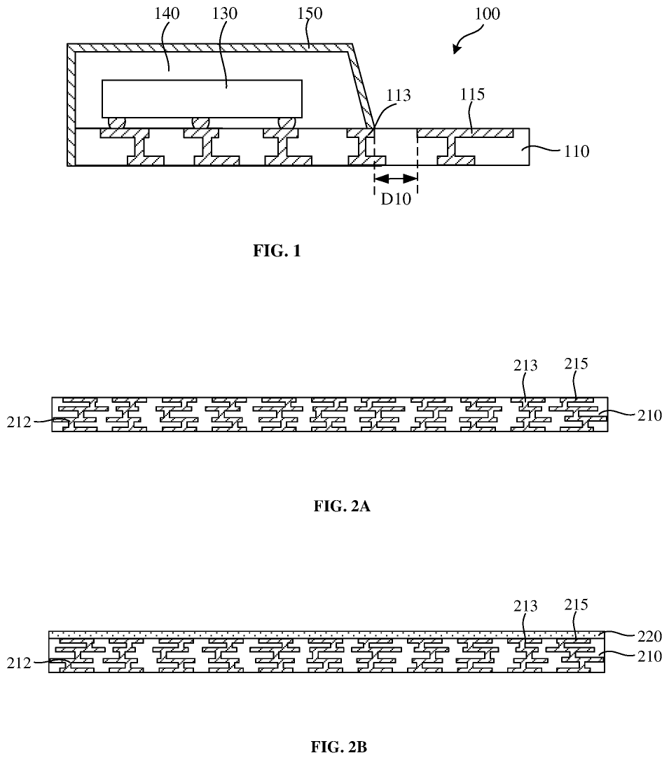

FIG. 1 illustrates a cross-sectional view of a partially molded or shield semiconductor device 100. The device 100 includes a substrate 110, an electronic component 130 mounted on the substrate 110, an encapsulant 140 covering the electronic component 130, and an electromagnetic interference (EMI) shield 150 formed on the encapsulant 140. A plurality of contact pads can be formed on the top surface of the substrate 110. Specifically, as shown in FIG. 1, a ground pad 113 and a connection pad 115 are formed on the top surface of the substrate 110. The ground pad 113 is connected with the EMI shield 150 to improve the EMI blocking performance. The connection pad 115 is outside of the encapsulant 140, and may be a board-to-board (B2B) pad to connect the package 100 to another semiconductor package including memory or logic circuits.

However, there is always a short clearance between the ground pad 113 and the connection pad 115, for example, a dimension D10 shown in FIG. 1. Consequently, when a conductive material is electroless-plated on the encapsulant 140 to form the EMI shield 150, extraneous plating may occur on the connection pad 115, resulting in defects such as shorted circuit between the ground pad 113 and the connection pad 115.

To address at least one of the above problems, a method for making a partially shielded semiconductor device is provided in an aspect of the present application. In the method, before forming the EMI shield, a coating layer is formed on the substrate and covers an area outside the encapsulant, and a laser hatching process is performed on the coating layer to remove a portion of the coating layer adjacent to the encapsulant to form a trench between the encapsulant and the coating layer. Then, the conductive material can only be electroless-plated on the encapsulant and the trench between the encapsulant and the coating layer. As the size of the trench can be accurately controlled by the laser, the conductive material is only plated at desired locations on the substrate. After the coating layer is removed from the substrate, a narrow clearance between the EMI shield and the connection pad or other exposed component can be achieved.

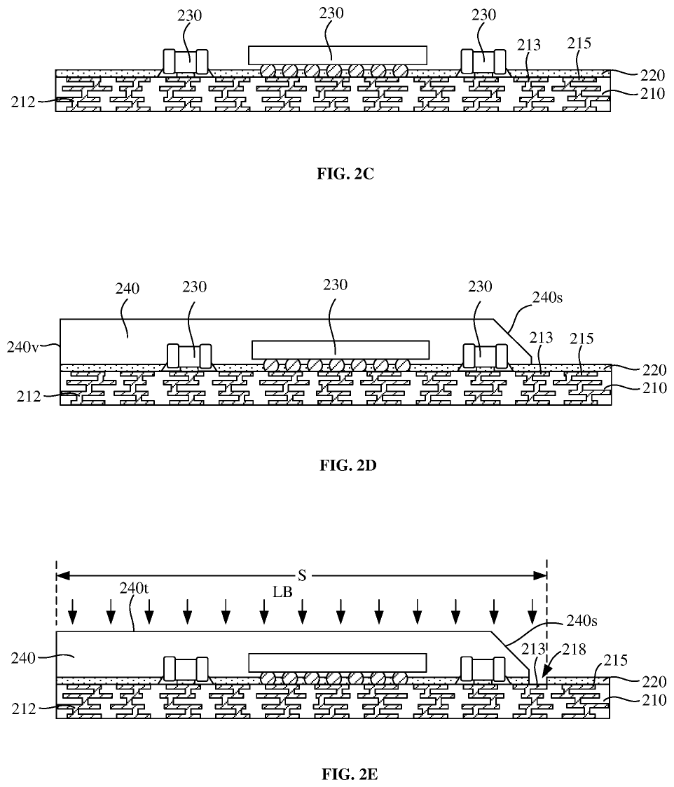

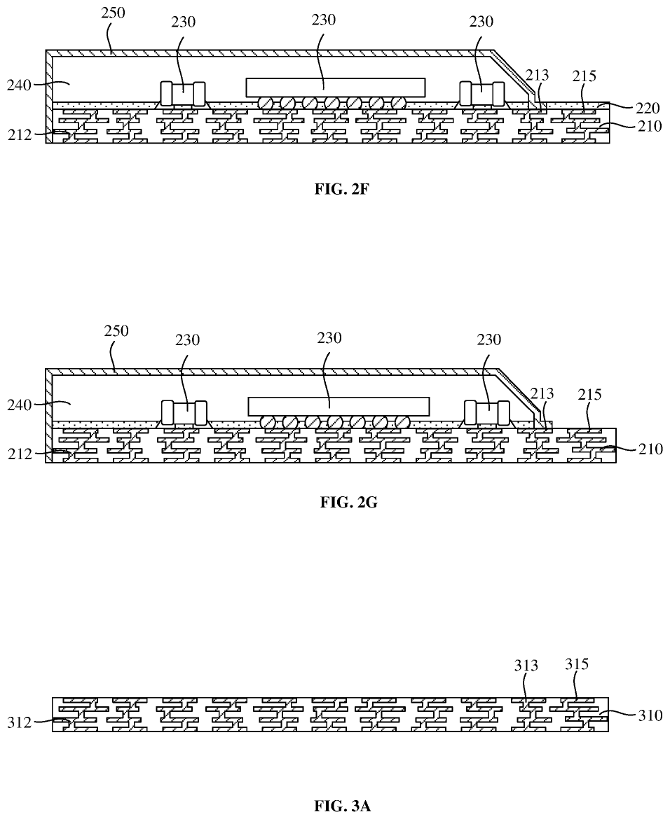

Referring to FIGS. 2A to 2G, cross-sectional views illustrating various steps of a method for making a partially shielded semiconductor device are shown according to an embodiment of the present application.

As shown in FIG. 2A, a substrate 210 is provided. The substrate 210 can provide support and connectivity for electronic components and devices.

By way of example, the substrate 210 can include a printed circuit board (PCB), a carrier substrate, a semiconductor substrate with electrical interconnections, or a ceramic substrate. However, the substrate 210 is not to be limited to these examples. In other examples, the substrate 210 may include a laminate interposer, a strip interposer, a leadframe, or other suitable substrates. The substrate 210 may include any structure on or in which an integrated circuit system can be fabricated. For example, the substrate 210 may include one or more insulating or passivation layers, one or more conductive vias formed through the insulating layers, and one or more conductive layers formed over or between the insulating layers.

In some embodiments, the substrate 210 may include a plurality of interconnection structures 212. The interconnection structures 212 can provide connectivity for electronic components mounted on the substrate 210. The interconnection structures 212 may include one or more of Cu, Al, Sn, Ni, Au, Ag, or any other suitable electrically conductive materials. In some examples, the interconnection structures 212 may include redistribution structures. The redistribution structures may include one or more dielectric layers and one or more conductive layers between and through the dielectric layers. The conductive layers may define pads, traces and plugs through which electrical signals or voltages can be distributed horizontally and vertically across the redistribution structures.

The interconnection structures 212 can provide contact pads along the top surface and the bottom surface of the substrate 210 for mounting devices, chips, and interconnects thereon.

For example, as shown in FIG. 2A, a ground pad 213 and a connection pad 215 are formed on the top surface of the substrate 210. The ground pad 213 and the connection pad 215 may be formed at a peripheral area of the substrate 210, and the connection pad 215 is farther away from the center of the substrate 210 than the ground pad 213. In some embodiments, the connection pad 215 may be a board-to-board (B2B) pad to connect the substrate 210 with another semiconductor package including memory or logic circuits, or any other external electronic devices. The B2B pad can provide electrical connections between two packages, which can case signal routing requirement of electronic devices and provide faster and more direct signal transmission.

In some embodiments, a plurality of solder bumps or solder balls may be formed on the contact pads along the bottom surface of the substrate 210. The solder balls are used to interface with an external device or attach the substrate 210 to an external device. In some embodiments, an antenna array may be formed on the bottom surface of the substrate 210, which can be connected with a radio frequency (RF) chip mounted the top of the substrate 210 through the interconnection structures 212.

Referring to FIG. 2B, a coating layer 220 is formed on the substrate 210. The coating layer 220 may cover the entire top surface of the substrate 210, including the ground pad 213 and the connection pad 215.

In some embodiments, the coating layer 220 may include a thiol functional organic compound and a surfactant. The thiol functional organics may include alkane thiols such as dodecanethiol, lauryl mercaptan, cetyl mercaptan, and stearyl mercaptan, as well as alkyl thioglycollate, stearyl thioglycollate, cetyl thioglycollate, methyl mercaptan, n-butyl mercaptan, cyclohexyl mercaptan, n-dodecyl mercaptan, n-propyl mercaptan, n-octyl mercaptan and t-nonyl mercaptan, by way of example and not limitation. The surfactant may include an ethoxylated alcohol. However, the present application is not limited to the above embodiments, and other suitable aqueous dispersions can be used in other embodiments as long as they can eliminate the possibility for extraneous plating.

In some examples, the coating layer 220 may include an aqueous dispersion such as “MID SelectCoat 100 FL” commercially available from MacDermid Inc. The “MID SelectCoat 100 FL” is an aqueous dispersion specially formulated to enhance plating performance on laser direct structured (LDS) substrates. For example, the “MID SelectCoat 100 FL” can be used to form redistribution layer (RDL) on LDS substrate. The “MID SelectCoat 100 FL” can be used to provide an adherent coating on a molded interconnect device (MID) prior to laser activation. Following laser activation, the coating is stripped using an alkaline cleaner which facilitates the removal of dust and debris formed during laser ablation of the substrate. In embodiments of the present application, the “MID SelectCoat 100 FL” is used to form the coating layer 220 to avoid extraneous plating.

In a specific example, the top surface of the substrate 210 is immersed in a solution made of the “MID SelectCoat 100 FL” at the room temperature for about 30-60 seconds, and then the substrate 210 is placed in an oven at 90° C. for about 40 minutes to dry the coating layer 220 formed on the substrate 210. In some cases, the substrate 210 may be spun for about 1-2 minutes after immersion, so as to get a uniform thickness of the coating layer 220.

Referring to FIG. 2C, one or more electronic components 230 are mounted on the top surface of the substrate 210.

The electronic components 230 may include any of a variety of types of semiconductor dice, semiconductor packages, or discrete devices. For example, the electronic components 230 may include one or more digital chips, analog chips or mixed signal chips, such as application-specific integrated circuit (“ASIC”) chips, sensor chips, wireless and radio frequency (RF) chips, memory chips, logic chips or voltage regulator chips. The electronic components 230 may also include one or more passive electronic components such as resistors, capacitors, inductors, etc. In some embodiments, the electronic components 230 may include an integrated circuit chip for wireless communication and/or signal processing, which may require antennas for transmitting and receiving wireless signals. In some embodiments, the electronic components 230 may further include output and/or input circuits for an antenna structure for wireless communication.

Depending on their structures and configurations, the electronic components 230 may be mounted on the contact pads formed on the top surface of the substrate 210 in a flip-chip configuration, or by wire bonding or any other suitable surface mounting techniques.

In the example shown in FIG. 2C, the electronic components 230 may have respective interconnection structures such as solder balls or bumps, and can be mounted on the contact pads formed on the top surface of the substrate 210 through these interconnection structures. In some embodiments, the interconnection structures of the electronic components 230 may penetrate the coating layer 220 to contact the contact pads on the top surface of the substrate 210 during the mounting process. In some embodiments, some portions of the coating layer 220 at positions where the electronic components 230 is to be mounted may be removed before the mounting process.

Referring to FIG. 2D, an encapsulant 240 is formed on the coating layer 220 to encapsulate the electronic components 230.

In some embodiments, the encapsulant 240 may be formed on the coating layer 220 using a compression molding process or an injection molding process. In some other embodiments, the encapsulant 240 may be formed using paste printing, transfer molding, liquid encapsulant molding, vacuum lamination, spin coating, or other suitable process. The encapsulant 240 may be made of polymer composite material, such as epoxy resin with filler, epoxy acrylate with filler, or polymer with proper filler, but the scope of this application is not limited thereto. The encapsulant 240 may protect the electronic component 230 from external elements and contaminants. In some examples, the encapsulant 240 may be planarized, if desired.

In some embodiments, the encapsulant 240 may include light-sensitive particles. The light-sensitive particles may be uniformly distributed inside the encapsulant 240 with a proper concentration. For example, the light-sensitive particles may be formed of a material that exhibits an electrically insulating property in a normal state and an electrically conductive property under the presence of light incident thereto. The light-sensitive particles may include conductive particles and a light-sensitive polymer. In some examples, each of the light-sensitive particles may include a core particle and a surface modifying layer coated on a surface of the core particle. The core particle may include a metal particle or a metal oxide particle, and the surface modifying layer may include a polymer containing a thiol group, a silane-based compound containing an alkoxy group, or acetylacetone.

In the example shown in FIG. 2D, the connection pad 215 and at least a portion of the ground pad 213 are exposed from a projection of the encapsulant 240 on the top surface of the substrate 210. The encapsulant 240 has a first lateral surface 240s adjacent to the ground pad 213 and a second lateral surface 240v away from the ground pad 213. The first lateral surface 240s may be extending at an acute angle to the top surface of the substrate 210, and the second lateral surface 240v may be extending in a vertical direction. In some embodiments, the first lateral surface 240s may be formed by a sloping sidewall of a mold used in the molding process. In some embodiments, in order to form multiple semiconductor devices simultaneously, a strip-based substrate may be used. After multiple instances of the electronic components 230 are mounted on the strip-based substrate, an encapsulant strip may be formed to encapsulating the electronic components 230. Afterwards, the strip-base substrate and the encapsulant can be singulated into individual semiconductor devices, and the second lateral surface 240v of the encapsulant 240 may be formed during the singulation process. However, the present application is not limited to the above embodiments, and the lateral surface of the encapsulant 240 may have different configurations as desired.

Referring to FIG. 2E, a laser hatching process is performed on the encapsulant 240 and a portion of the coating layer 220 adjacent to the encapsulant 240 to remove the portion of the coating layer 220 to form a trench 218 in the coating layer 220.

Specifically, as shown in FIG. 2E, a laser beam LB is illuminated onto an area S including the top surface 240t of the encapsulant 240, the first lateral surface 240s of the encapsulant 240 and a portion of the coating layer 220 adjacent to the encapsulant 240. The laser beam LB can ablate the illuminated coating layer 220 to form the trench 218 in the coating layer 220. After the illuminated coating layer 220 is ablated, at least a portion of the ground pad 213 can be exposed from the remaining coating layer 220, but the connection pad 215 is still covered by the remaining coating layer 220. As the laser hatching process can be accurately controlled by adjusting the laser size and pattern, the trench 218 can be accurately formed with the desired size and at the desired location.

As shown in FIG. 2E, the laser hatching process is also performed on the top surface 240t and the first lateral surface 240s of the encapsulant 240 to transform light-sensitive particles at the top surface 240t and the first lateral surface 240s of the encapsulant 240 to conductive particles. The conductive particles exposed from the top surface 240t and the first lateral surface 240s of the encapsulant 240 can serve as a seed layer in a subsequent electroless plating process. In other words, the laser hatching process is also a plating catalyst activation step. For example, when the laser beam LB is illuminated onto the top surface 240t and the first lateral surface 240s of the encapsulant 240, the surface modifying layer of the light-sensitive particle is broken down, and the core particle of the light-sensitive particle can be exposed through the top surface 240t and the first lateral surface 240s of the encapsulant 240. Further, the laser hatching process may create a micro-etched surface that provides excellent bonding characteristics for the electroless metal that is subsequently applied thereto.

Afterwards, referring to FIGS. 2E and 2F, a conductive material is electroless-plated to form an EMI shield 250. The EMI shield 250 covers the encapsulant 240 and fills the trench 218 in the coating layer 220.

In some embodiments, a layer of encapsulant material with conductive particles exposed from the top surface 240t and the first lateral surface 240s can serve as a seed layer in the electroless-plating process. Moreover, the ground pad 213 exposed from the coating layer 220 can also serve as a seed layer. Thus, the conductive material can be electroless-plated on the top surface 240t and the first lateral surface 240s of the encapsulant 240, and can fill the trench 218 in the coating layer 220. Thus, the EMI shield 250 can be in direct contact with the ground pad 213. The conductive material may include a metallic material, such as Cu, Ni, Au, Ag, Pt, Co, Ti, Cr, Zr, Mo, Ru, Hf, W, Re, or the like.

In some embodiments, as stated above, the strip-base substrate and the encapsulant may be singulated to form multiple semiconductor devices simultaneously. During the singulation process, the surface modifying layer and/or the core particle of the light-sensitive particle at the second lateral surface 240v of the encapsulant 240 may be damaged, and a lateral surface of the substrate 210 may be activated. Thus, the core particles of the light-sensitive particles exposed on the second lateral surface 240v of the encapsulant 240 can also serve seeds in the electroless-plating process. Thus, the conductive material can be electroless-plated on the second lateral surface 240v of the encapsulant 240 and the activated surface of the substrate 210.

As the connection pad 215 is covered by the coating layer 220, there may be no conductive material formed on the connection pad 215. In other words, the conductive material can be selectively plated at areas activated by the laser hatching process or the singulation process. Thus, the occurrence of extraneous plating can be substantially eliminated or significantly reduced, and there is no risk for metal burrs after forming the EMI shield.

Afterwards, referring to FIGS. 2F and 2G, the coating layer 220 covering the connection pad 215 is removed from the substrate 210.

Specifically, after the conductive material has accumulated to a sufficient thickness, the electroless-plating process stops, and the coating layer 220 covering the connection pad 215 can be stripped off the top surface of the substrate 210, such that the connection pad 215 can be exposed. In an example, an alkaline cleaner can be used to strip the coating layer 220 off the substrate 210. However, the present application is not limited thereto.

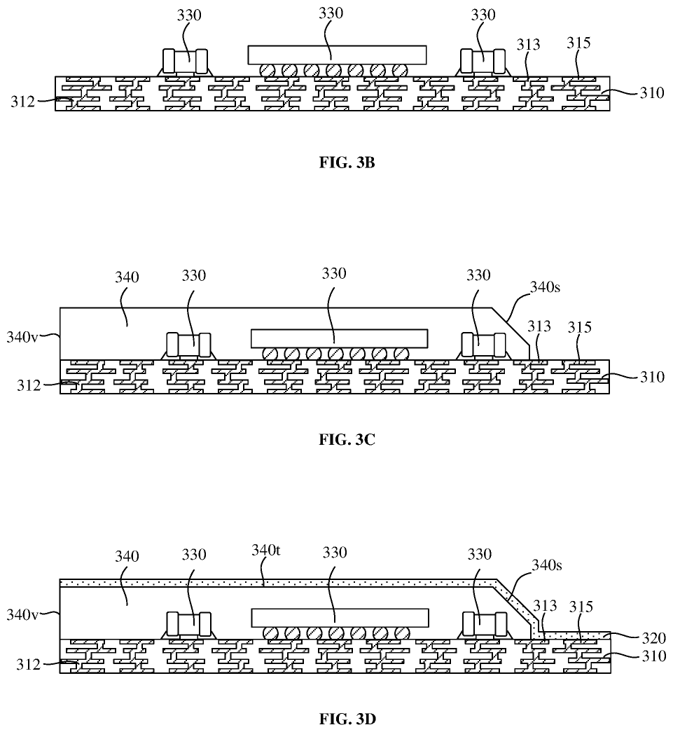

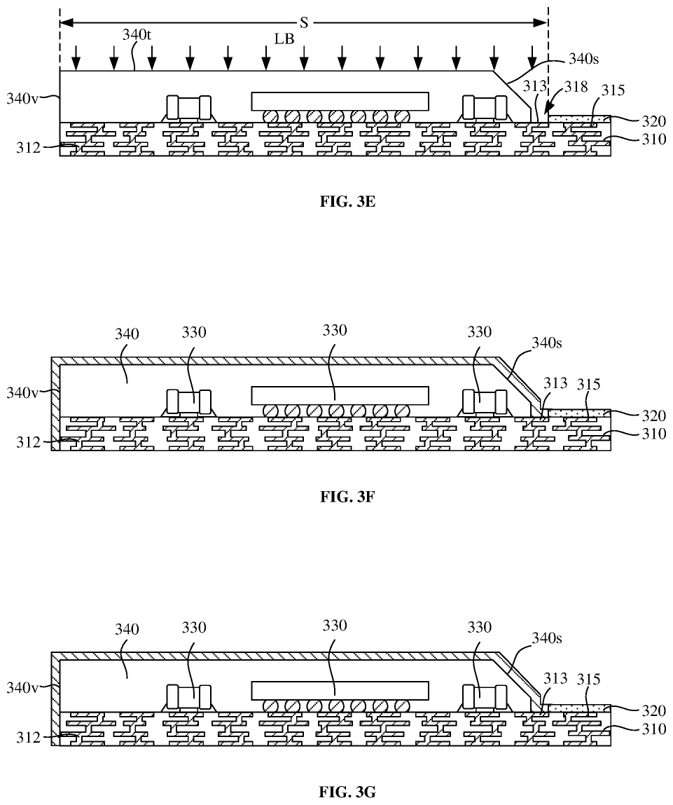

Referring to FIGS. 3A to 3G, cross-sectional views illustrating various steps of a method for making a partially shielded semiconductor device are shown according to another embodiment of the present application. The steps similar as those steps described with reference to the embodiment illustrated in FIGS. 2A to 2G will not be repeated.

As shown in FIG. 3A, a substrate 310 is provided. The substrate 310 may include a plurality of interconnection structures 312. The interconnection structures 312 can provide connectivity for electronic components mounted on the substrate 310. For example, a ground pad 313 and a connection pad 315 are formed on the top surface of the substrate 310. The ground pad 313 and the connection pad 315 may be formed at a peripheral area of the substrate 310, and the connection pad 315 is farther away from the center of the substrate 310 than the ground pad 313.

Referring to FIG. 3B, one or more electronic components 330 are mounted on the top surface of the substrate 310. The electronic components 330 may include any of a variety of types of semiconductor dice, semiconductor packages, or discrete devices. For example, the electronic components 330 may include one or more digital chips, analog chips or mixed signal chips, such as application-specific integrated circuit (“ASIC”) chips, sensor chips, wireless and radio frequency (RF) chips, memory chips, logic chips or voltage regulator chips. The electronic components 330 may be mounted on the contact pads formed on the top surface of the substrate 310 in a flip-chip configuration, or by wire bonding or any other suitable surface mounting techniques.

Referring to FIG. 3C, an encapsulant 340 is formed on the top surface of the substrate 310 to encapsulate the electronic components 330.

In some embodiments, the encapsulant 340 may include light-sensitive particles. The light-sensitive particles may be uniformly distributed inside the encapsulant 340 with a proper concentration. For example, the light-sensitive particles may be formed of a material that exhibits an electrically insulating property in a normal state and an electrically conductive property under the presence of light incident thereto. The light-sensitive particles may include conductive particles and a light-sensitive polymer. In the example shown in FIG. 3C, the connection pad 315 and at least a portion of the ground pad 313 are exposed from a projection of the encapsulant 340 on the top surface of the substrate 310. The encapsulant 340 has a first lateral surface 340s adjacent to the ground pad 313 and a second lateral surface 340v away from the ground pad 313. The first lateral surface 340s may be extending at an acute angle to the top surface of the substrate 310, and the second lateral surface 340v may be extending in a vertical direction.

Referring to FIG. 3D, a coating layer 320 is formed on the encapsulant 340. The coating layer 320 may cover the top surface 340t and the first lateral surface 340s of the encapsulant 340, and the ground pad 313 and the connection pad 315 formed on the top surface of the substrate 310.

In some embodiments, the coating layer 320 may include a thiol functional organic compound and a surfactant. For example, the coating layer 320 may include an aqueous dispersion such as “MID SelectCoat 100 FL” commercially available from MacDermid Inc.

Referring to FIG. 3E, a laser hatching process is performed on the encapsulant 340 to remove the coating layer 320 formed on the top surface 340t and the first lateral surface 340s of the encapsulant 340, and to remove a portion of the coating layer 320 adjacent to the encapsulant 340 to form a trench 318 between the encapsulant 340 and the coating layer 320.

Specifically, as shown in FIG. 3E, a laser beam LB is illuminated onto an area S including the top surface 340t of the encapsulant 340, the first lateral surface 340s of the encapsulant 340 and a portion of the coating layer 320 adjacent to the encapsulant 340. The laser beam LB can ablate not only the coating layer 320 formed on the top surface 340t and the first lateral surface 340s of the encapsulant 340, but also the portion of the coating layer 320 adjacent to the encapsulant 340 to form the trench 318 between the encapsulant 340 and the coating layer 320. After the illuminated coating layer 320 is ablated, at least a portion of the ground pad 313 can be exposed by the trench 318, but the connection pad 315 is still covered by the remaining coating layer 320.

Further, the laser hatching process performed on the top surface 340t and the first lateral surface 340s of the encapsulant 340 can transform light-sensitive particles at the top surface 340t and the first lateral surface 340s of the encapsulant 340 to conductive particles. The conductive particles exposed from the top surface 340t and the first lateral surface 340s of the encapsulant 340 can serve as seeds in a subsequent electroless plating process.

Afterwards, referring to FIGS. 3E and 3F, a conductive material is electroless-plated to form an EMI shield 350. The EMI shield 350 covers the encapsulant 340 and fills the trench 318 between the encapsulant 340 and the coating layer 320.

In some embodiments, the ground pad 313 exposed by the trench 318 and the conductive particles exposed from the top surface 340t and the first lateral surface 340s of the encapsulant 340 can serve as a seed layer in the electroless-plating process, and thus the conductive material can fill the trench 318 in the coating layer 320, and can be electroless-plated on the top surface 340t and the first lateral surface 340s of the encapsulant 340. In some embodiments, a strip-base substrate and encapsulant may be singulated to form multiple semiconductor devices simultaneously. During the singulation process, the surface modifying layer and/or the core particle of the light-sensitive particle at the second lateral surface 340v of the encapsulant 340 may be damaged, and a lateral surface of the substrate 310 may be activated. Thus, the core particle of the light-sensitive particle exposed at the second lateral surface 340v of the encapsulant 340 can also serve a seed layer in the electroless-plating process. Thus, the conductive material can be electroless-plated on the second lateral surface 340v of the encapsulant 340 and the activated surface of the substrate.

Afterwards, referring to FIGS. 3F and 3G, the coating layer 320 covering the connection pad 315 is removed from the substrate 310. For example, an alkaline cleaner can be used to strip the coating layer 320 off the substrate 310.

While different processes for making the partially shielded semiconductor device are illustrated in conjunction with FIGS. 2A-2G, and FIGS. 3A-3G, it will be appreciated by those skilled in the art that modifications and adaptations to the processes may be made without departing from the scope of the present invention. For example, a redistribution layer, rather than an EMI shield, can be formed based on the conductive material formed in FIG. 2F or 3F, or both the redistribution layer and the EMI shield can be formed based on the conductive material formed in FIG. 2F or 3F.

According to another aspect of the present application, a partially shielded semiconductor device is provided.

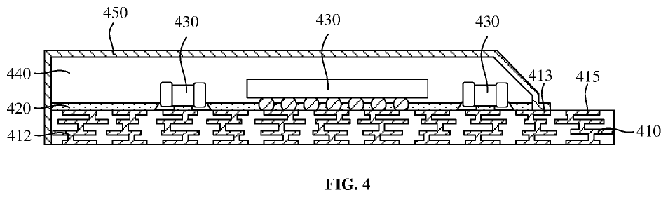

Referring to FIG. 4, a cross-sectional view of a partially shielded semiconductor device 400 is illustrated according to an embodiment of the present disclosure.

The partially shielded semiconductor device 400 may include: a substrate 410; an electronic component 430 mounted on the substrate 410; an encapsulant 440 formed on the substrate 410 and encapsulating the electronic component 430; a coating layer 420 formed between the substrate 410 and the encapsulant 440; and an electromagnetic interference (EMI) shield 450 covering the encapsulant 440.

In some embodiments, the coating layer 420 may include a thiol functional organic compound and a surfactant. In some embodiments, the encapsulant 440 may include a plurality of light-sensitive particles inside the encapsulant 440 and a plurality of conductive particles at a top surface and a lateral surface of the encapsulant 440. In some embodiments, the substrate 410 may include a ground pad 413 and a connection pad 415 formed thereon, and the connection pad 415 is farther away from the electronic component 430 than the ground pad 413. In some embodiments, the ground pad 413 may be electrically connected with the EMI shield 450, and the connection pad 415 is exposed from the encapsulant 440 and the EMI shield 450.

The partially shielded semiconductor device 400 can be formed by the steps illustrated in FIGS. 2A to 2G. Thus, more details about the partially shielded semiconductor device 400 may refer to the above method embodiments, and will not be elaborated herein.

While the partially shielded semiconductor device of the present application is described in conjunction with corresponding figures, it will be understood by those skilled in the art that modifications and adaptations to the partially shielded semiconductor device may be made without departing from the scope of the present invention.

The discussion herein included numerous illustrative figures that showed various portions of a partially shielded semiconductor device and method of manufacturing thereof. For illustrative clarity, such figures did not show all aspects of each example device. Any of the example devices and/or methods provided herein may share any or all characteristics with any or all other devices and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for making a partially shielded semiconductor device, comprising:
providing a package comprising:
a substrate;
an electronic component mounted on the substrate;
an encapsulant formed on the substrate and encapsulating the electronic component; and
a coating layer formed on the substrate and adjacent to the encapsulant;
performing a laser hatching process on the encapsulant and a portion of the coating layer adjacent to the encapsulant to remove the portion of the coating layer to form a trench between the encapsulant and the coating layer; and
electroless-plating a conductive material to cover the encapsulant and fill the trench between the encapsulant and the coating layer.

2. The method of claim 1, wherein the coating layer comprises a thiol functional organic compound and a surfactant.

3. The method of claim 1, wherein providing the package comprises:
providing the substrate;
forming the coating layer on the substrate;
mounted the electronic component on the substrate; and
forming the encapsulant on the coating layer to encapsulate the electronic component.

4. The method of claim 3, wherein the encapsulant has a plurality of light-sensitive particles dispersed therein, and performing the laser hatching process on the encapsulant comprises:
performing the laser hatching process on a top surface and a lateral surface of the encapsulant to transform light-sensitive particles at the top surface and the lateral surface of the encapsulant to conductive particles.

5. The method of claim 1, wherein providing the package comprises:
providing the substrate;
mounted the electronic component on the substrate;
forming the encapsulant to encapsulate the electronic component; and
forming the coating layer to cover the encapsulant and the substrate.

6. The method of claim 5, wherein the encapsulant has a plurality of light-sensitive particles dispersed therein, and performing the laser hatching process on the encapsulant comprises:
performing the laser hatching process on a top surface and a lateral surface of the encapsulant to remove the coating layer covering the top surface and the lateral surface of the encapsulant and transform light-sensitive particles at the top surface and the lateral surface of the encapsulant to conductive particles.

7. The method of claim 1, wherein the substrate comprises a ground pad and a connection pad formed thereon, and the connection pad is farther away from the electronic component than the ground pad.

8. The method of claim 7, wherein the trench exposes the ground pad, and the conductive material filling the trench is electrically connected with the ground pad.

9. The method of claim 7, wherein the coating layer covers the connection pad.

10. The method of claim 1, further comprising:
removing the coating layer from the substrate.

11. A partially shielded semiconductor device, comprising:
a substrate;
an electronic component mounted on the substrate;
an encapsulant formed on the substrate and encapsulating the electronic component;
a coating layer formed between the substrate and the encapsulant; and
an electromagnetic interference (EMI) shield covering the encapsulant.

12. The partially shielded semiconductor device of claim 11, wherein the coating layer comprises a thiol functional organic compound and a surfactant.

13. The partially shielded semiconductor device of claim 11, wherein the encapsulant comprises a plurality of light-sensitive particles inside the encapsulant and a plurality of conductive particles at a top surface and a lateral surface of the encapsulant.

14. The partially shielded semiconductor device of claim 11, wherein the substrate comprises a ground pad and a connection pad formed thereon, and the connection pad is farther away from the electronic component than the ground pad.

15. The partially shielded semiconductor device of claim 14, wherein the ground pad is electrically connected with the EMI shield, and the connection pad is exposed from the encapsulant and the EMI shield.
